(19) United States
(12) Patent Application Publication
(10) Pub. No.: US 2013/0285525 A1
(43) Pub. Date: Oct. 31, 2013

(54) FOLDING DEVICE

(71) Applicants: HONG FU JIN PRECISION INDUSTRY (SHENZHEN) CO., LT, Shenzhen (CN); HON HAI PRECISION INDUSTRY CO., LTD., New Taipei (TW)

(72) Inventors: TING-TING ZHAO, Shenzhen (CN); HE-LI WANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/705,371

(22) Filed: Dec. 5, 2012

(30) Foreign Application Priority Data
Apr. 25, 2012 (CN) 201210123404.0

(51) Int. Cl. H05K 5/02

(52) U.S. Cl. CPC H05K 5/0239
USPC 312/319.2

(57) ABSTRACT

A folding device includes a housing, a cover, at least one pivoting member, a torsion spring, and at least one resisting member. The cover folds down on the housing. The pivoting member is fixed to the cover. The pivoting member has a pivot. The pivot is rotatably inserted into the housing to pivot the cover on the housing. The torsion spring provides a constant elastic force for opening and supporting the cover. The at least one resisting member resists against the pivoting member to prevent the pivot disengaging from the housing.

### BACKGROUND

1. Technical Field

The present disclosure relates to folding devices, and particularly to a folding electronic device.

2. Description of Related Art

Folding devices, such as DVD players, include a main body defining two pivot holes, a cover having two pivots, and two torsion springs. The two pivot holes are positioned at opposite ends of the main body. The pivots protrude from opposite ends of the cover in the same direction. The torsion springs provide a force to open and support the cover. However, the torsion springs commonly support asymmetric positions of the cover because of the structure of the folding device. When the cover is closed, the torsion spring not only develops a stronger force for opening the cover, but the force encourages the pivots to disengage from the pivot holes, such that the cover may move upwards under the force causing an undesirable space to be formed between the cover and the main body.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of a folding device in an open state, the folding device includes a resisting member.

FIG. 2 is an exploded view of the folding device in FIG. 1.

FIG. 3 is an inverted view of the folding device in FIG. 2.

FIG. 4 is an isometric view of the resisting member in FIG. 1.

FIG. 5 is an inverted view of the resisting member in FIG. 4.

FIG. 6 is a partial enlarged view of the folding device of FIG. 1 but viewed from an inverted aspect.

### DETAILED DESCRIPTION

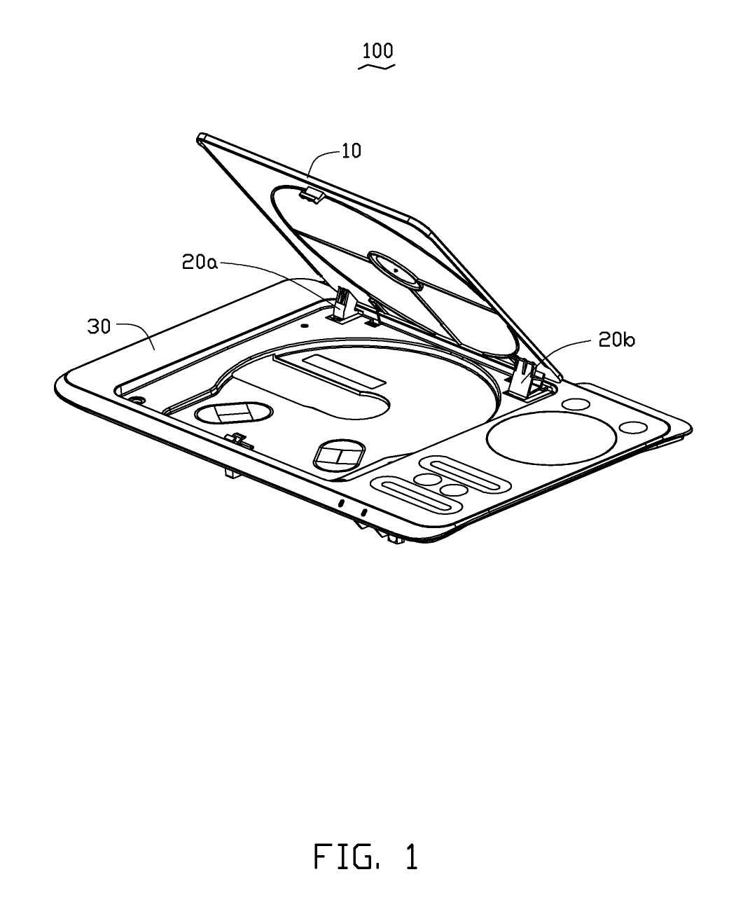

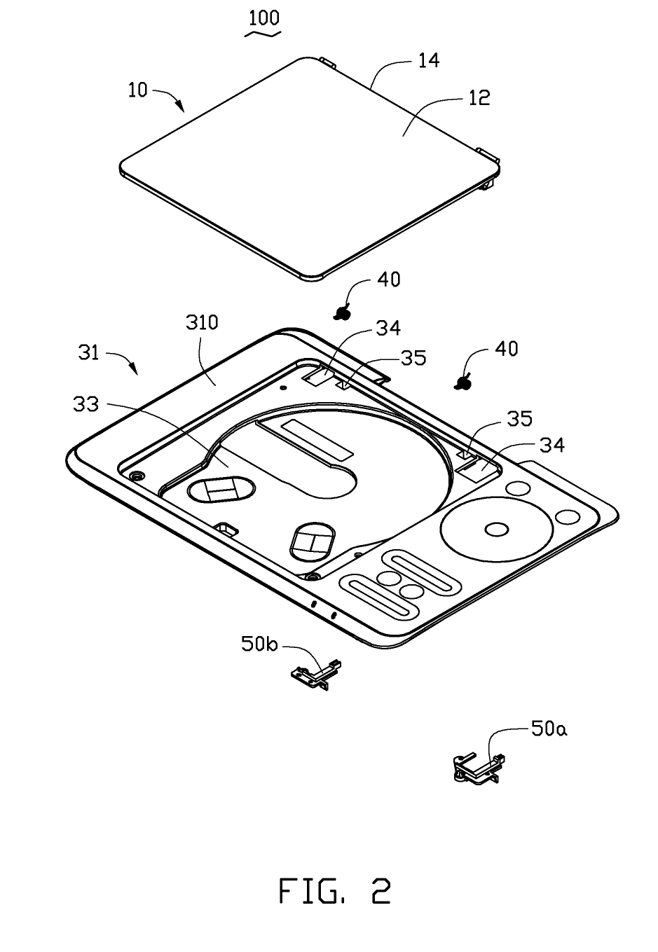

Referring to FIGS. 1 and 2, a folding device 100 in accordance with an embodiment is shown. In this embodiment, the folding device 100 is a DVD player. The folding device 100 includes a cover 10, two pivoting members 20a, 20b, a housing 30, two torsion springs 40, and two resisting members 50a, 50b. The pivoting members 20a and 20b protrude from the cover 10, the pivoting members 20a, 20b pivot on the housing 30 to enable the cover 10 to rotate about the housing 30. The cover 10 is capable of being folded down on the housing 30. The torsion springs 40 provide a constant elastic force urging the cover 20 to open. The resisting members 50a, 50b resist the pivoting members 20 to prevent the pivot members 20 disengaging from the housing 30.

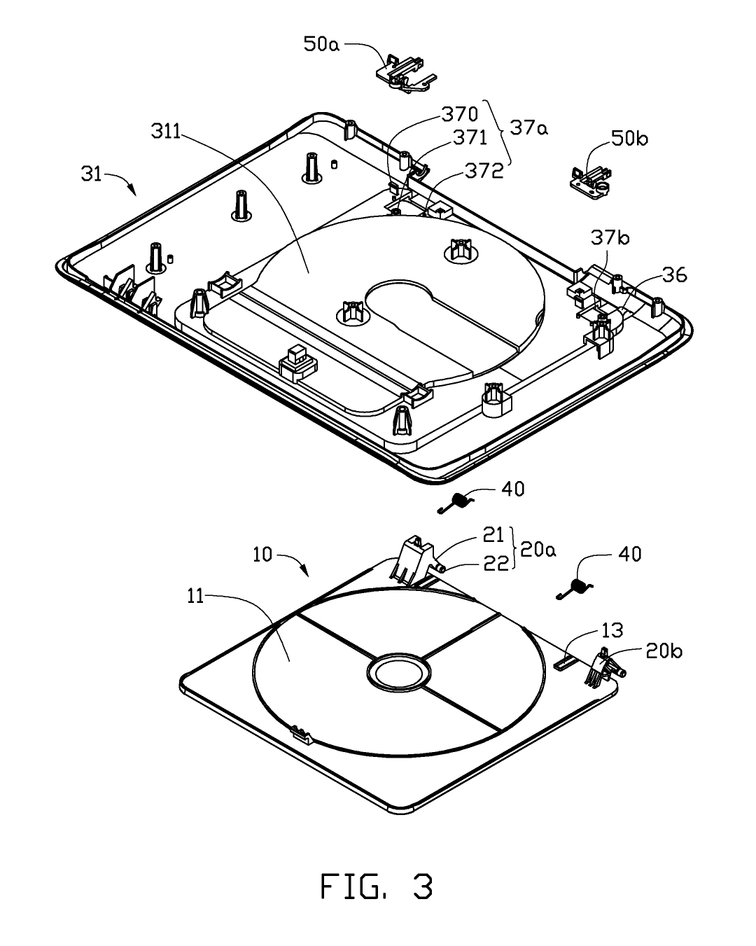

Referring to FIG. 3, one side 14 of the cover 10 is connected to the housing 30. The cover 10 is rectangular. The cover 10 includes a first surface 11 facing the housing 30, and a second surface 12 opposite to the first surface 11. The first surface 11 defines two positioning slots 13 adjacent to the side 14.

The pivoting members 20a, 20b are located in the first surface 11, adjacent to the side 14, and symmetrical about the center of the cover 10. The pivoting members 20a, 20b are adjacent to the positioning slots 13. The distance between the pivoting member 20a and the nearest positioning recess 13 is different from the distance between the pivoting member 20b and the position recess 13 nearest the pivoting member 20b. Each of the pivoting members 20a, 20b includes a main body 21, and a pivot 22. The pivot 22 extends from the main body 21 parallel to the side 14. Therefore, the pivot 22 of the pivoting member 20a is between the two main bodies 21 of the pivoting members 20a and 20b. The pivot 22 of the other pivot member 20b is not between the two main bodies 21 of the pivoting members 20a and 20b.

The housing 30 includes an upper casing 31, and a lower casing (not shown). The upper casing 31 is assembled to the lower casing to form a receiving space to receive electronic components (not shown). The upper casing 31 includes a top surface 310, a bottom surface 311 opposite to the top surface 310, a receiving part 33, two positioning grooves 35, two connecting parts 36, and two securing parts 37a, 37b. The receiving part 33 is positioned in the middle of the upper casing 31. Viewed from the top surface 310, the receiving part 33 is recessed into the top surface. Viewed from the bottom surface 311, the receiving part 33 protrudes from the bottom surface 311. The size of the receiving part 33 fits the cover 10. The cover 10 is received in the receiving part 33 and the first surface 11 and the top surface 310 are coplanar when the cover 10 is folded down on the housing 30. The receiving part 33 defines two openings 34 through the top surface 310 and the bottom surface 311. The openings 34 correspond to the pivoting members 20a and 20b to allow the pivoting members 20a and 20b to pass through the upper casing 31. The connecting parts 36 protrude from the bottom surface 311, and are adjacent to the openings 34. Each connecting part 36 defines a pivot hole (not shown). The pivot 22 is received in the pivot hole, such that the cover 10 is pivoted to the housing 30. The receiving grooves 35 are defined in the upper casing 31, the receiving grooves 35 are adjacent to the openings 34 and are located between the openings 34. The receiving grooves 35 correspond to the positioning slots 13.

Each of the securing parts 37a and 37b includes a hook 370, a screw post 371, and two positioning posts 372. The hook 370, the screw post 371, and positioning posts 372 are arranged around the openings 34. The difference between the securing part 37a and the securing part 37b is that the layout of the screw posts 371 and positioning posts 372 is different.

Each torsion spring 40 includes spring body 41, a first end 42, and a second end 43. The first end 42 and the second end 43 extend from opposite ends of the main body 41. The first end 41 is positioned in the positioning slot 13. The main body 41 and the second end 43 are secured in the positioning groove 35.

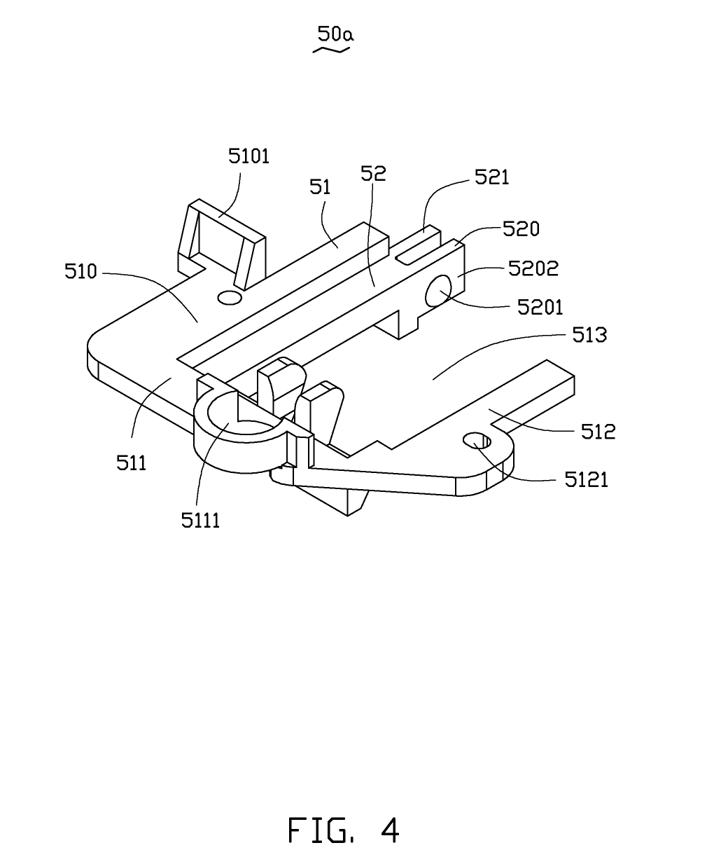

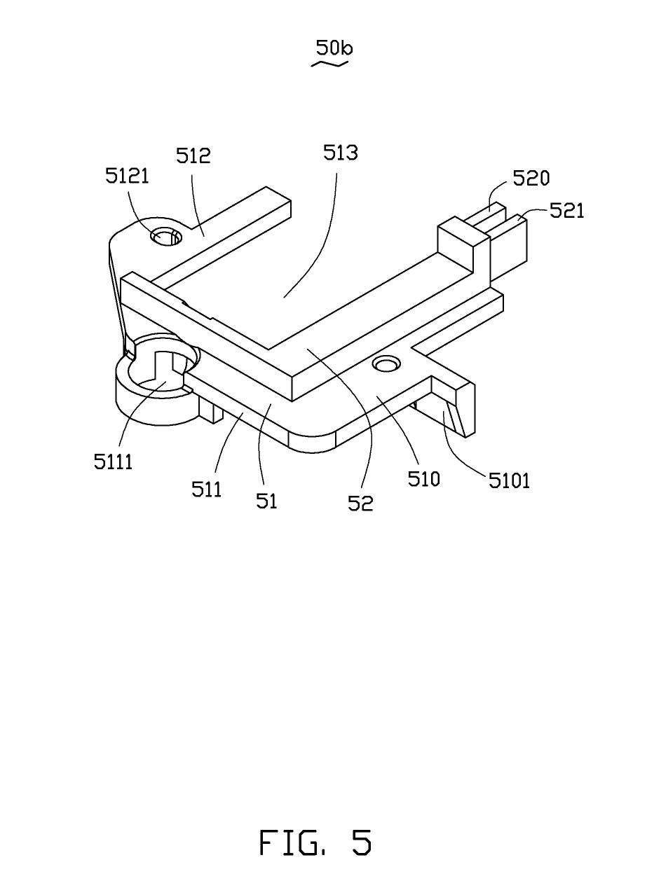

Referring to FIGS. 4 and 5, the resisting members 50a, 50b are secured to the upper casing 31. The resisting member 50a includes a securing part 51, and a blocking arm 52 protruding from the securing part 51. The securing part 51 is fixed to bottom surface 311. The securing part 51 includes a first fixing board 510, second fixing board 512, and a third fixing board 511. The first fixing board 510 is parallel to the third fixing board 512 and there is a space 513 between the first fixing board 510 and third fixing board 512. The third fixing board 511 is connected between the first fixing board 510 and the second fixing board 512. The surfaces of the first fixing board 510, the third fixing board 511, and the second fixing board 512 facing the upper casing 31 are all coplanar. A clasping member 5101 perpendicularly protrudes from the first fixing board 510 toward the upper casing 31, and corresponds to the hook 370. A sleeve 5111 protrudes from the middle of the third fixing board 511, and corresponds to the screw post 371. Two positioning holes 5121 corresponding to the positioning posts 372 are defined in the second fixing board 512 and the first fixing board 510. The blocking arm 52 is positioned at the first fixing board 510, and faces the upper casing 31. A first blocking board 520 and a second blocking board 521 extend from one end of the blocking arm 52 and are located outside of the first fixing board 510. The first and the second blocking boards 520 and 521 are elastic. The first blocking board 520 faces the second fixing board 512. A hemispherical tab 5201 perpendicularly protrudes from one side 5202 of blocking board 520 toward the second fixing board 512.

The resisting member 50b is similar to the resisting member 50a. The differences between the resisting members 50b and 50a are that the resisting member 50b omits the third fixing board 512, the sleeve 5111 and the positioning holes 5121 are located in the third fixing board 511, the positioning holes 5121 are defined in the middle of the third fixing board 511, and the sleeve 5111 protrudes from the distal end of the third fixing board 511.

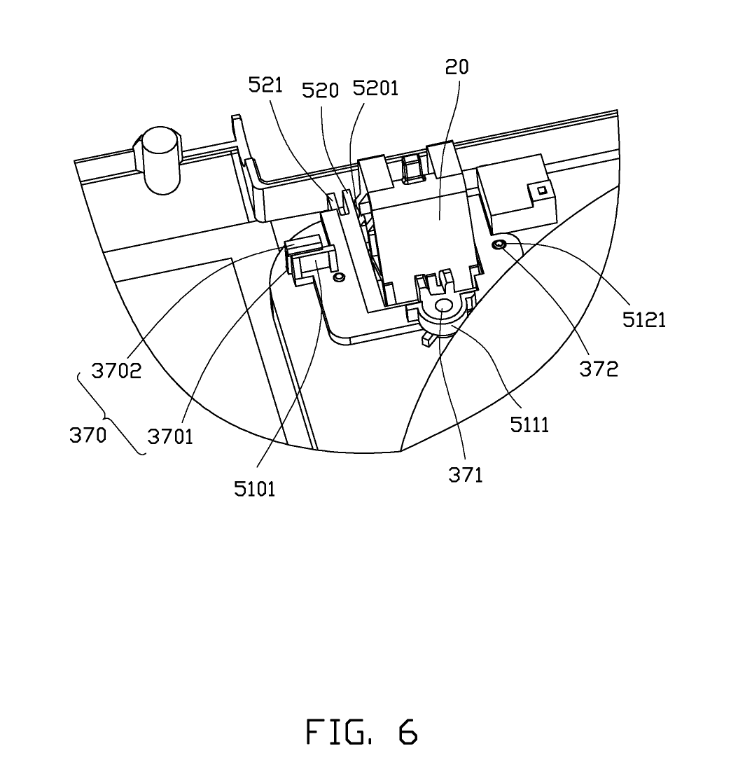

Referring to FIG. 6, the assembly of the resisting member 50a is shown. First, the positioning posts 372 are passed through the positioning holes 5121, the screw post 371 is passed through the sleeve 5111, the hook 370 is clasped by the clasping member 5101, and a screw (not shown) is screwed into the screw post 371 such that the resisting member 50 is secured to the upper casing 31. At this time, the tab 5201 of the resisting member 50 resists one side of the pivoting members 20 away from the pivot 22. The blocking board 521 is away from the pivoting members 20 and supports the upper casing 31. Assembly of the resisting member 50b is the same as assembly of the resisting member 50a.

When the cover 10 is folded down on the housing 30, the tab 5201 resists one side of the pivoting member 20 away from the pivot 22. Therefore, the pivot 22 cannot disengage from the connecting parts 36, the torsion springs 40 cannot force the cover 10 to deviate from the proper position. An undesirable gap between the cover 10 and the housing 30 does not exist.

Even though relevant information and the advantages of the present embodiments have been set forth in the foregoing description, together with details of the functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. A folding device, comprising:
a housing;
a cover capable of being folding down on the housing;
at least one pivoting member fixed to the cover, the pivoting member having a pivot, the pivot being rotatably inserted into the housing to pivot the cover on the housing;
a torsion spring providing an elastic force for opening and supporting the cover; and
at least one resisting member resisting against the pivoting member to prevent the pivot from disengaging from the housing.

2. The folding device of claim 1, wherein the pivoting member further comprises a main body, the pivot extends from one side of the main body, the resisting member resists against the other side of the main body opposite to the pivot.

3. The folding device of claim 1, wherein the number of the pivoting member is two, pivots of the pivoting members extend toward the same direction.

4. The folding device of claim 1, wherein the resisting member comprises a securing part, and a blocking arm, the securing part is secured to the housing, the blocking arm protrudes from the securing part, one side of the blocking arm resists the housing, the other side of the blocking arm resists against the pivoting member.

5. The folding device of claim 4, wherein a tab protruding from one side of the blocking arm to resist the pivoting member.

6. The folding device of claim 5, wherein a first blocking board, and a second blocking board extend from a distal end of the blocking arm at interval, the tab is positioned on the first blocking board.

7. The folding device of claim 6, wherein the first and the second blocking board is capable of being deformed when the tab resists against the pivoting member.

8. A folding device, comprising:
a housing;
a cover capable of being folding down on the housing;
at least one pivoting member fixed to the cover, the pivoting member having a main body and a pivot extending from a first side of the main body, the pivot being rotatably inserted into the housing to pivot the cover to the housing;
a torsion spring providing an elastic force for opening and supporting the cover; and
at least one resisting member resisting against a second side of the main body opposite the first side.

9. The folding device of claim 8, wherein the number of the pivoting member is two, pivots of the pivoting members extend toward the same direction.

10. The folding device of claim 8, wherein the resisting member comprises a securing part, and a blocking arm, the securing part is secured to the housing, the blocking arm protrudes from the securing part, one side of the blocking arm resists the housing, the other side of the blocking arm resists the pivoting member.

11. The folding device of claim 10, wherein a tab protrude from one side of the blocking arm to resist the pivoting member.

12. The folding device of claim 11, wherein a first blocking board, and a second blocking board extend from a distal end of the blocking arm at interval, the tab is positioned on the first blocking board.

13. The folding device of claim 12, wherein the first and the second blocking board is capable of being deformed when the tab resists against the pivoting member.
